(19) United States
(12) Patent Application Publication
(10) Pub. No.: US 2024/0397826 A1
(43) Pub. Date: Nov. 28, 2024

(54) SYSTEMS AND METHODS FOR OLIGOMERIC DUFFING OSCILLATORS

(71) Applicant: Molecular Machines Corporation Ltd., Tel Aviv (IL)

(72) Inventors: Vladik AVETISOV, Moscow (RU); Roman ILIEV, Baku (AZ)

(21) Appl. No.: 18/696,452

(22) PCT Filed: Sep. 27, 2022
(86) PCT No.: PCT/IB2022/059205

§ 371 Date: Mar. 28, 2024

Related U.S. Application Data
(60) Provisional application No. 63/249,072, filed on Sep. 28, 2021.

(51) Int. Cl. H10N 30/00; H02N 2/18; H10N 30/857

(52) U.S. Cl. CPC H10N 30/101; H02N 2/186; H10N 30/857

(57) ABSTRACT

Disclosed are nanomechanical devices whose functioning is related to bistability, spontaneous vibrations, and/or stochastic resonance of nanoscale oligomeric structures and/or their nanoscale compositions. Spring-type oligomeric machines are disclosed as well as their use in energy harvesting.

### CROSS-REFERENCES TO RELATED APPLICATIONS

This application claims priority to U.S. provisional application No. 63/249,072 filed Sep. 28, 2021; the disclosure of which is incorporated herein by reference in its entirety.

### FIELD

Disclosed are nanomechanical devices whose functioning is related to bistability, spontaneous vibrations, and/or stochastic resonance of nanoscale oligomeric structures and/or their nanoscale compositions.

### BACKGROUND

Industrial miniaturization of devices and machines is typically carried out by top-down design. The creation of smaller and smaller components and devices is desired, and manufacturing is moving to the nanometer scale from the micrometer scale. Approaching the size of about 10 nm by top-down design, the cost of precise manipulations using macroscopic devices typically increases and may become prohibitively expensive. Alternatively, bottom-up strategies which design functional devices on the nanometer scale from building elements of sub-nanometer (atomic) size may prove beneficial.

Nanoscale molecular structures, whose long-term dynamics are similar to the motion of bistable mechanical systems, are attracting increasing attention due to the intensive design and practical implementation of a wide range of nanodevices acting as switches and logic gates, sensors and actuators, mechanoelectric transductors and energy harvesters. Nanoscale bistable systems acting as ultrasensitive elements capable of detecting single molecules are also in demand for many important applications. The detection of trace concentrations of, e.g., toxic chemicals and explosives, as well as the precise control of drugs and biologically active substances in compartments of a micron size, is of interest.

Typically, stochastic disturbances such as thermal fluctuations of a sensing element by its surroundings limits detection at the molecular level. However, bistable oligomeric machines exhibiting thermally activated spontaneous vibrations and/or stochastic resonance may use such environmental noise to amplify, rather than distort, a weak signal. Spontaneous vibrations and/or stochastic resonance may be exhibited by oligomeric machines employing nonlinear bistable systems and may manifest itself near the critical point at which the bistability emerges.

Two types of bistable mechanical systems can be considered as prototypes of nanoscale molecular structures to which oligomeric molecular machines are addressed. These are the Euler arches, which looks like elastic rods, and the Duffing oscillator, which are springs with nonlinear elasticity. Both of the prototypes can be considered as one-dimensional dynamical systems with critical behavior exhibiting bistability in a particular range of the force loading. For example, an elastic rod slightly compressed in the longitudinal direction remains straight. However, as soon as the compressive force exceeds a critical value, the straightened state becomes unstable and bifurcates into two arcuate states of the rod. In energy terms, a potential energy function with a single minimum corresponding to the stability of the straightened state governs the dynamics of sub-critically compressed Euler arch. In contrast, the potential of the Euler arch subjected to super-critical compression has two energy wells corresponding to two symmetric arcuate states, which are separated from each other by the bistability barrier. Accordingly, sub-critically compressed Euler arch behaves as a bistable system able to switch-like transitions between the two states driven with force loads.

Besides deterministic transitions between the two states controlled by force loads, spontaneous jumps between these states, i.e., spontaneous vibrations, can be activated by noisy-like random disturbance of the bistable system. In the spontaneous vibration mode, the time intervals separating spontaneous jumps, i.e., the lifetimes of the system in its states, are random values distributed around an average lifetime, which exponentially grows with the ratio of the bistability barrier to the noise intensity. Therefore, the spontaneous vibrations are observed when this ratio is not too large, e.g., the bistability barrier is an order of magnitude greater than the noise intensity. In turn, spontaneous vibrations can be transformed into almost regular, but still noise-induced switching between the two states by wiggling of the bistable potential and/or modulation of the bistability barrier via weak oscillating forces. This phenomenon is called stochastic resonance. Along with spontaneous vibrations, stochastic resonance is a striking manifestation of bistability.

In fact, stochastic resonance is peculiar unusual combination of the non-linear dynamics of the system and its stochastic perturbations, with which the noise amplifies a weak signal rather than blurring it. To date, some experimental evidence has been obtained that the bistable patterns might present in scales down to sub-micron, for instance, in nanotubes, graphene sheets, DNA hairpins, and proteins. In this regard, it should be noted that spontaneous vibrations and stochastic resonance of macroscopic mechanical systems, even if they are in a micron-sized range, are not likely to be activated by environmental thermal noise. The bistability barriers of macroscopic systems are much higher than the thermal noise intensity (˜k_{B} T): much stronger perturbations are required to activate the spontaneous vibrations and stochastic resonance in mechanics even of the micron-scale.

Nanoscale mechanics, however, may offer a different set of characteristics. With nanoscale mechanics, the bistability barrier of a bistable nanoscale system may be high enough to separate two states of the system relative to thermal noise. The same barrier may also be low enough to allow the activation of the transitions by the thermal-bath fluctuations. A value of about ten for the ratio of the bistability barrier to the noise intensity can serve as a reasonable guide. Some oligomeric molecules, their size within a few nanometers, could be assumed as such bistable systems. Indeed, bistable molecules demonstrating the bistable dynamics similar to those of the Euler arches were recently found through intensive molecular dynamic simulations of short thermoresponsive oligomeric compounds and oligomeric compositions subjected to force loads. The simulations showed mechanic-like bistability of these oligomeric molecules with spontaneous vibrations and stochastic resonance activated by thermal fluctuations.

### BRIEF DESCRIPTION OF DRAWING(S)

FIG. 1 depicts an exemplary molecular machine comprising a pyridine-furan spring with 5 monomer units.

FIG. 2 depicts computational models of an exemplary oligo-PF-5 system with applied longitudinal load. FIG. 2a depicts computational models of an exemplary oligo-PF-5 system with applied longitudinal load; FIG. 2b depict bistability of an exemplary oligo-PF-5 spring; FIGS. 2c and 2d depict spontaneous vibrations of oligo-PF-5 spring.

FIG. 3 depicts stochastic resonance of an exemplary oligo-PF-5 induced by an oscillating field.

FIG. 4 depicts bistability of an exemplary oligo-PF-7 spring.

FIG. 5 depicts stochastic resonance of an exemplary oligo-PF-7 induced by an oscillating field.

FIG. 6 depicts a computational model of two exemplary oligo-PF-5 springs rigidly coupled by an oligomeric beam.

FIG. 7 depicts spontaneous vibrations of an exemplary system of two rigidly coupled PF-springs.

FIG. 8 depicts stochastic resonance of an exemplary system of two rigidly coupled PF-springs induced by weak oscillating force.

### DETAILED DESCRIPTION

The present disclosure relates to a bottom-up design strategy for molecular machines. In contrast to using small molecule components as building elements, an aspect of the disclosure relates to a strategy to directly utilize rigid structures on the nanometer scale. The presented concepts recognize three physical phenomena, which may be combined to enable structural elements of a composition to move relative to each other, thereby providing a nano-mechanical functionality for the composition. Amongst the disclosed embodiments are oligomeric compositions of a few nanometers in size that possess the property of conformational bistability.

The disclosure of PCT/US20/65562, filed Dec. 17, 2020, is incorporated by reference.

A first phenomenon is nanomechanics, which enables the possibility to realize machine-like movements using molecular units of a nanometer size. From a general view, machine-like movement implies low-dimensional collective movements of rather rigid molecular units, which atomic fluctuations are much less, than the structures characteristic sizes, as well as the scale of their movements. Because the atomic fluctuations at room temperature are of the order of 1 Angstrom, the minimal size of the functional units will generally not be significantly less than 1 nanometer. In some embodiments of a nano-mechanical device, the functional unit is an oligomeric spring able to become elongated and/or shortened; wherein the nano-mechanical device comprises oligomeric fragments of the pyridine-furan (PF) polymer with a length of about 5 monomeric units. The characteristic size of elongation and/or shortening of this spring is about 10 angstroms (1 nanometer), and the characteristic scale of its atomic fluctuations in water at room temperature generally does not exceed 1 angstrom (0.1 nanometers).

A second phenomenon is the advantage of utilizing oligomeric compositions. Oligomeric springs or linked oligomeric springs (with differing chemical and/or configurational properties) enables the possibility of machine-like movements of rigid oligomeric units of nanometer size. In other words, a basic functional element of some embodiment molecular machines that realize mechanical motion, is an oligomer or block-co-oligomer units comprising and/or consisting of oligomeric fragments differing chemically and/or configurationally. In particular, the functional elements can be realized from single oligomeric spring of 5 PF-units of isotactic configuration, or, from single oligomeric spring of 7 PF-units of isotactic configuration, or from block-co-oligomer composition composed of two PF-springs of 5 units of isotactic configuration joint together by a rigid bar of 4 pyrrole units, or from multiple PF springs of 5 units joint together by a graphene sheet.

A third phenomenon is conformational bistability, which is characterized, on the one hand, by the existence of two well distinguishable conformational states of oligomeric composition and, on the other hand, by the reproducible transitions between such states controlled by some external parameter. Reproducible transitions between well-specified conformational states of oligomeric compositions of a few nanometers in size may enable the mechanical-like movements and can be initiated by an external action.

In some embodiments, the present disclosure relates to bistable oligomeric machines like Duffing oscillators, which long-term dynamics possess mechanic like bistability accompanied with thermally activated spontaneous vibrations and stochastic resonance.

In some embodiments, a nano-mechanical device comprises short nano-sized oligomeric structures stabilized by short-range, low-energy atomic interactions, e.g., weak hydrogen bonds, hydrophilic-hydrophobic interactions, and IT-IT interactions, exhibit bistability with thermally activated spontaneous vibrations and stochastic resonance. Examples include pyridine-furan springs and/or their combinations, which possess nonlinear elasticity caused by the TT-TT interactions between aromatic groups located on the adjacent turns of the PF-springs. From dynamical point of view, a mechanical prototype of the nanoscale PF-springs is the Duffing oscillator.

Duffing oscillators form a class of non-linear dynamical systems specified by damped oscillations of springs having non-linear elasticity. Deterministic dynamics of a Duffing oscillator obeys the following Newtonian equation:

$$( d \hat{} 2 x ) / ( dt \hat{} 2 ) + k dx / dt = - ( d U ( x ) ) / dx , \qquad ( 1 )$$

Here, x is a deviation of a unit mass from the position x=0 (hereinafter this position is referred to as the median zero-stress point), k is a damping parameter, and U(x)=ax\hat{ }2+bx\hat{ }4,b>0, is a four-degree potential of a spring. It is assumed that the spring elasticity changes linearly at small deviations x, while it increases non-linearly at large deviations x. Given positive elasticity coefficient, a, the potential U(x) has single extremum (minimum) located at the median zero-stress point x=0, so the spring experiences damped oscillations around this point. At large deviations from the median zero-stress point, the nonlinear effects such as non-isochronism and anharmonicity may accompany the oscillations. However, the potential U(x) becomes bistable if the linear elasticity coefficient a is negative. In this case, the spring has three zero-stress points (x_1=0,x_2,3=± [symbol] (−a/(2b)) [symbol] \hat{ }(½). Two of them (x_2 and x_3) specify the attraction basins located at large deviations from the median zero-stress point, while this point becomes unstable and repulses the dynamic trajectories. Therefore, depending on the values of the parameters k, a, and b, the Duffing oscillator either has one stable attractor in the form of a node or a spiral point, or it is bistable and has two attractive nodes or spiral points. To be bistable, the spring should have such an elasticity that decreases the elastic energy with small deviations from the median zero-stress point, and increases the elastic energy with large deviations x.

Bistable springs manifest the richest behavior when random perturbations and oscillating forces are applied to them. In such cases, the dynamics of bistable springs are described by the Langevin equation of the form:

$$( d \hat{} 2 x ) / ( dt \hat{} 2 ) + k dx / dt = - 2 a x - 4 bx \hat{} 3 = 2 ε f ( t ) + {E}_{0} cos ( ω t ) , \qquad ( 2 )$$

where a<0 and b>0, f(t) denotes a zero-mean, Gaussian white noise with autocorrelation function [symbol] f(t),f(0) [symbol] =δ(t), and the last term in the right-hand part of equation (2) is an external field oscillating with a circular frequency ω.

The interest in the action of random perturbations and oscillating field on bistable springs is since random perturbations can activate random transitions between the two attracting basins of the spring, while the oscillating field can force the regular transitions between the attracting basins. As a result, the dynamics of a nonlinear spring turn out to be multimodal, in contrast to the dynamics of a linear spring. In addition to deterministic behavior associated with non-damped or weekly-damped oscillations in a single attracting basin, bistable spring can exhibit spontaneous vibrations and stochastic resonance caused by random and forced transitions between the two basins, respectively. The implementation of bistability, spontaneous vibrations, and stochastic resonance using nano-sized springs immersed in the thermal bath as the only source of random perturbations could be of the greatest interest.

Provided herein are computer simulations demonstrating bistable Duffing oscillators. In some embodiments, short pyridine-furan springs are oligomeric springs with soft low-energy coupling of the turns due to TT-TT stacking and possess the bistable dynamics characteristic of a Duffing oscillator. Moreover, beside the two-state deterministic dynamic, an oligomeric Duffing oscillator can exhibit thermally activated spontaneous vibrations and stochastic resonance.

Provided herein are atomistic simulations of short PF-springs subjected to stretching and some embodiments of the springs clearly exhibit bistable dynamics characteristic of Duffing oscillators. Some embodiments may include two short springs designed from PF-oligomers with 5 and 7 monomer units. In some embodiments, the dynamics of the oligo-PF-5 spring were studied with one end of the spring was fixed, while another end was pulled by the force applied along the axis of the spring. The tensile of the oligo-PF-7 springs had been achieved by fixing both ends of the spring on controlled distance. In some embodiments, characteristics of bistability, such as spontaneous vibrations and stochastic resonance, were established for both springs and were examined in wide ranges of controlling parameters to find the symmetrical bistability conditions. In some embodiments, at these conditions, we defined the mean lifetime of the states in the spontaneous vibration mode of each spring. Using these life times and following Kramer's rate approximation with the collisions time ranged from 0.1-10 ps, in some embodiments, the bistability barriers of both springs are 10-15 k_{B}T. In some embodiments, the time scales of spontaneous vibrations of the oligo-PF-5 and the oligo-PF-7 springs and their bistability barriers are approximately the same as those of the oligomeric Euler arch described in PCT/US20/65562. The bistability barriers of short PF-springs are high enough to separate the two states against the thermal noise, and, on the other hand, the same barriers allowed activation of the transitions between the two states by energetically enriched thermal fluctuations.

Thus, our modelling of short PF-springs and antecedent modelling of the oligomeric Euler arches give some reasons to believe that nano-sized oligomeric structures stabilized by short-range low-energy coupling by, e.g., weak hydrogen bonds, hydrophilic-hydrophobic interactions, and π-π interactions, can exhibit bistability with thermally activated spontaneous vibrations and stochastic resonance. However, the proof requires challenging experimentations. In some embodiments, a system of coupled oligomeric Duffing oscillators comprises two oligomeric-PF-5 springs connected together by a rigid oligomeric bar.

In some embodiments, a system of coupled oligomeric Duffing oscillators, and micron or larger functional elements with a large number of PF springs exhibit spontaneous oscillations and stochastic resonance. In some embodiments, a chip of molecular machines combines the macroscopic size of the device and the nanoscopic sensitivity of oligomeric functional elements to weak external impacts for single molecule detecting or thermal energy collecting.

### Examples

### Pyridine-Furan Springs as Bistable Duffing Oscillators

### Materials and Methods

### Pyridine-Furan Springs

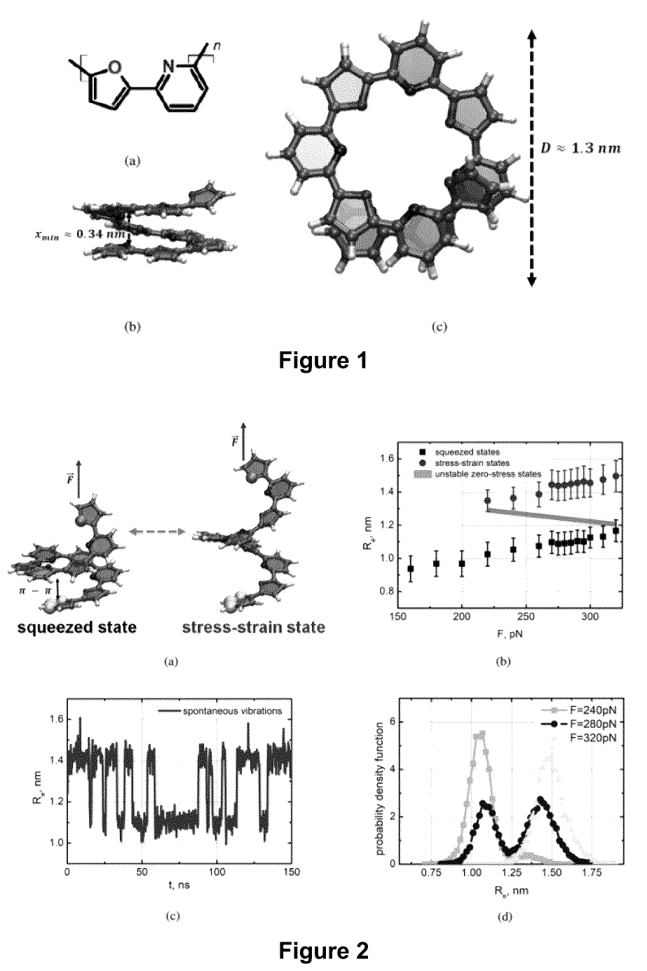

Pyridine-furan (PF) copolymer (FIG. 1a) is a conductive polymer comprising 5-membered and 6-membered heterocyclic rings. The PF-copolymers tend to form a helix-like shape, which is squeezed by the π-π interactions of aromatic groups located at the adjacent turns. Assuming that the stacking could lead to nonlinear elasticity of the PF-springs, and following the quantum calculations of the stacking energy for different configurations of heterocyclic rings, the cis-configuration of oligo-PF with heteroatoms of the 5-membered and the 6-membered heterocyclic rings on one side of a polymer chain were chosen (see FIG. 1a). Then, the probing samples of the PF-springs were screened by molecular dynamic simulations to specify the spring sizes and the spring tensile that proved the non-linear elasticity of the spring. The distance between the adjacent turns was close to 0.35 nm in all non-stretched samples.

Guided by the screening of sizes, two models of PF-springs consisting of 5 monomer units (oligo-PF-5) (see FIG. 1b,c) and 7 monomer units (oligo-PF-7) were designed. The specificity of these models was that each of those springs had only one turn between the ends. It should be noted that longer PF-springs with several turns typically had many degrees of freedom associated with the movements of the turns relative to each other. These inter-turn movements made interpretation of the long-term dynamics of the spring ambiguous when comparing with the Duffing dynamics given by the equation (1). Thus, in fact, the oligo-PF-5 and oligo-PF-7 springs were chosen to have as short springs as possible, providing, on the one hand, a helix-like shape of the oligomer with the stacking of aromatic groups, and, on the other hand, a well-defined degree of freedom associated with long-term dynamics of the spring.

FIG. 1 depicts a pyridine-furan spring with 5 monomer units (oligo-PF-5 spring): (a) depicts the chemical structure of a pyridine-furan monomer unit with heterocyclic rings in cis-configuration. (b) depicts the front and (c) depicts top views of an oligo-PF-5 spring in the atomistic representation. The spring has one complete turn consisting of approximately 3.5 monomer units.

### Simulation Details

The oligo-PF-springs and the environmental water were modeled in a fully atomistic representation with a canonical (NVT) ensemble (box size: 7.0×7.0×7.0 nm³) with a time step of 2 fs using Gromacs 2019 and the OPLS-AA force field parameters for the oligomer, and SPC/E model for water. The temperature was set at 280 K by the velocity-rescale thermostat, which corresponds to the equilibrium state of PF-springs. Each dynamic trajectory was 300-350 ns long and was repeated three times to obtain better statistics, therefore the effective length of the trajectories was about one microsecond for each sample.

When studying the dynamics of the oligo-PF-5, one end of the spring was fixed, while the other end was pulled by a force applied along the axis of the spring. The distance (denoted Re) between the ends of the oligo-PF-5 spring (yellow and blue balls in FIG. 2a) was considered as a collective variable describing the long-term dynamics of the spring. Bistability of the oligo-PF-5 spring was specified in correspondence to two well reproducible states of the spring with the end-to-end distances equal to Rₑ˜1.10 nm and Rₑ˜1.45 nm. These states are referred to as the squeezed and the stress-strain states, respectively.

FIG. 2a depicts computational models of the oligo-PF-5 system with applied longitudinal load. The squeezed state and the stress-strain state of the spring are shown on the left and right, respectively. The spheres at the lower end of the spring indicate the fixation of the pyridine ring by rigid harmonic force. The pulling force F is applied to the top end of the spring. (b) The state diagram shows a linear elasticity of oligo-PF-5 spring up to F≈220 pN and bistability of the spring in the region from F≈220-320 pN; (c) Spontaneous vibrations of the oligo-PF-5 spring at F≈279 pN; (d) Evolution of the probability density for visiting the squeezed and stress-strain states when pulling force passes the critical value. A symmetrical bistable probability density distribution exists at F≈279 pN.

The tensile of the oligo-PF-7 springs was modelled in a different way. A pulling force was not used in this case, rather the distance between the fixed ends of the spring was the controlling parameter. Since the spring ends attracted the turn due to the π-π interactions, the turn could sway between the fixed ends in a manner mimicking a pendulum. Accordingly, the states of the oligo-PF-7 spring were described by the distance P between a marked atomic group on the turn and one of the spring ends, e.g., the left one. Bistability of the oligo-P-7 spring was specified by means of two well reproducible positions of the turn with P˜0.40 nm, and P˜0.65 nm, respectively. Since these two states are associated with the closeness of the turn either to the left end or to the right end of the spring, these states are referred to as the left-end and the right-end states of the spring.

The statistics of visiting the two states were extracted directly from Rₑ(t) and P(t) time series. The spectral characteristics of spontaneous vibrations and stochastic resonance were defined by the power spectra calculated using the Fourier transform of the autocorrelation functions [symbol] Rₑ(t),Rₑ(t+τ) [symbol] ₜ and [symbol] P(t),P(t+τ) [symbol] ₜ, respectively.

### Bistable Dynamics of the Oligo-PF-5 Spring

To examine the dynamics of the oligo-PF-5 springs subjected to the tension, the oligo-PF-5 spring was equilibrated at 280 K with one end fixed, and then pulled another end by the force F directed along the spring axis. At weak tensile, the initial state squeezed by the stacking remained stable: the spring was stretching slightly in accordance with the linear elasticity. However, as soon as the pulling force reached some critical value, the oligo-PF-5 spring became bistable and started to vibrate spontaneously. Atomistic snapshots of these two states are shown in FIG. 2a. Critical value of the pulling force is well seen in the state diagram shown in FIG. 2b. Under weak tensile, there is only one zero-stress point: it linearly shifts in accordance with the increasing pulling force (black points in FIG. 2b). Hence, the damped oscillations characterize the spring dynamics at the weak tensile. As soon as the pulling force reaches the critical value about of F_{c}=240 pN, a junction point occurs, which then splits onto the branch of zero-stress attractors (red points on FIG. 2b), which is referred to as the stress-strain states, and the branch of unsteady zero-stress states repulsing the dynamic trajectories (solid line in FIG. 2b).

At the same time, the squeezed states remain attractive (black points on FIG. 2b. In terms of nonlinear dynamical systems, the oligo-PF-5 spring dynamics bifurcate at the critical force F_{c}=240 pN. Above the critical tensile, the spring becomes bistable and spontaneously vibrates between the squeezed and the stress-strain states. The mean value of the end-to-end distances of the spring in the squeezed and the stress-strain states differ approximately by 0.35 nm, so the stress-strain states are vastly distinguished from the squeezed states. Note, that this difference implies extending of the stacking pair length almost in twice. Therefore, the π-π interactions do not make significant contribution to the elastic energy of the stress-strain states, and the spring elasticity is mainly determined by the rigidity of the oligomeric backbone.

FIG. 2d shows the evolution of the statistics of visits of the squeezed state and the stress-strain state when the pulling force passes the critical point F_{c}. Below F_{c}, the squeezed state is the only steady state of the spring. At the bifurcation point F_{c}, the stress-strain state appears and the oligo-PF-5 spring becomes bistable: it spontaneously vibrates, yet the squeezed state dominates near the critical point F_{c}. The squeezed and the stress-strain states are almost equally visited in the region from F≈270-290 pN, that is, the oligo-PF-5 bistability becomes approximately symmetrical reasonably far from the critical point.

In the whole region of bistability, the mean lifetimes of the squeezed and the stress-strain states varied from τ=1-40 ns, depending on the pulling force (see [6]). In the symmetrical bistability region nether the squeezed state no the stress-strain state dominates, so the mean lifetimes of the two states are approximately the same and equal to τ≈6.14 ns. In the symmetrical bistability region, spontaneous vibrations of the oligo-PF-5 spring are the most pronounced. Following Kramer's rate approximation with the collision time for random perturbations ranged from 0.1-10 ps, one can roughly estimate the bistability barrier of the oligo-PF-5 spring as of 10-15 k_{B}T. Interesting, that the bistability barrier of the oligomeric-PF-5 spring turns out to be roughly equal to the same value as that of the oligomeric Euler arch described in PCT/US20/65562. Despite the fact that the reasons for bistability of the oligo-PF-5 spring and the oligomeric Euler arch are different, the bistability barriers of both bistable oligomeric systems are about ten times larger than the characteristic scale of thermal fluctuations k_{B}T.

FIG. 2c shows a typical trajectory of the long-term dynamics Rₑ(t) of the oligo-PF-5 spring in the symmetric bistability region. Spontaneous vibrations of the spring are seen unambiguously. Note, that no extra random perturbations were applied to the spring to activate spontaneous vibrations: they were activated purely by the thermal-bath fluctuations. Outside the bistability region there were non-vibrating trajectories.

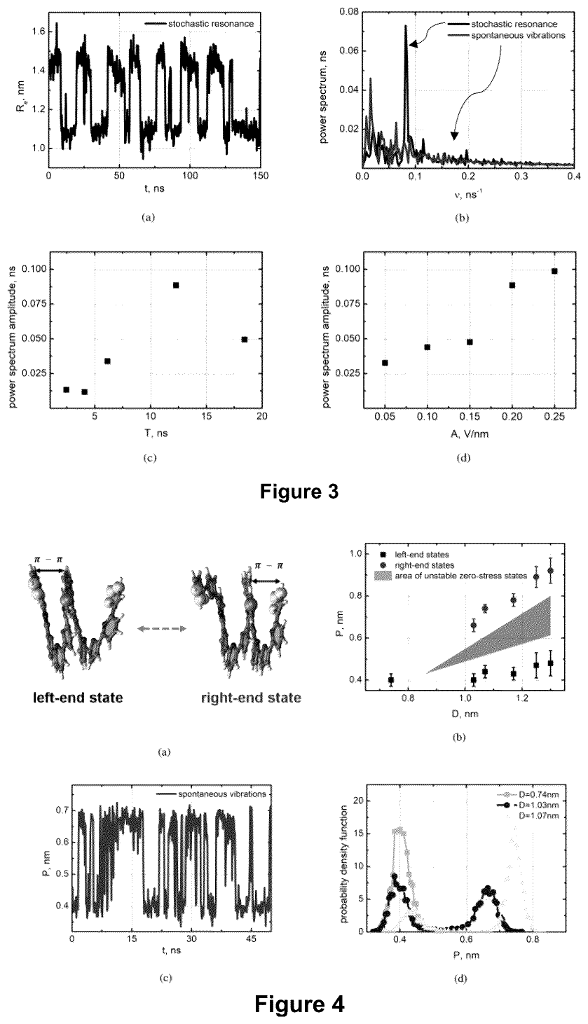

Next, the stochastic resonance mode of the oligoPF-5 spring was examined by applying an additional oscillating force waved weakly the pulling end of the spring. The oscillating force was modelled by the action of an oscillating electrical field E=E₀ cos(2πvt) on a unit charge preset on the pulling end of the spring, while a compensative charge was on the fixed end. Typical vibrations of the end-to-end distance of the oligo-PF-5 spring in the stochastic resonance mode and the power spectrum of the vibrations are shown in FIG. 3.

FIG. 3 depicts stochastic resonance of the oligo-PF-5 induces by an oscillating field E=E₀ cos(2π/T) in the symmetric bistability conditions: (a) The dynamic trajectory at F=279 pN, T=12.28 ns, and E₀=0.2 Vnm⁻¹; (b) Power spectrum of spontaneous vibrations (red curve) and stochastic resonance (black curve); (c) The dependence of the main resonance peak amplitude on the period T of oscillating field (E₀=0.2 Vnm⁻¹); (d) The dependence of the main resonance peak amplitude on E₀ T=12, 28 ns.

The main resonance peak was observed at the frequency

$$v = 1 / 2 τ ,$$

i.e., the period of the applied oscillating field was equal to twice the mean lifetime of the state in the spontaneous vibration mode. In fact, a wide range of oscillating fields were scanned to find the maximal resonance response defined in terms of the spectral component at the resonance frequency. Corresponding results are presented in FIG. 3c,d. The maximal resonance response was observed exactly when the period of the oscillating field was close to twice the mean lifetime of the states in the spontaneous vibrations mode. Regarding the amplitude of the oscillating field, the maximal resonance was found for E₀=0.2 Vnm⁻¹. It should be noted that the resonance response was screened in the region of symmetric bistability at F=279 pN. Beyond the symmetric bistability region, the lifetimes of the squeezed and the stress-strain states became so different that the averaged lifetime ceases to be a good guide for resonance frequency.

### Bistable Dynamics of the Oligo-PF-7 Spring

Another realization of the PF-springs with the Duffing bistability, was based on competition between the stacking sites. Here, two competing attractors at the ends of the spring are created so that the turn would swing between the ends like a pendulum. Here, a slightly longer PF-oligomer with 7 monomer units, oligo-PF-7 spring, was designed so that the aromatic groups on the turn could form a stacking pair with either the right end or the left end of the spring. The equilibrated state of the oligo-PF-7 spring matched the squeezed state of the oligo-PF-5 spring with the stacking distance close to 0.35 nm. In this state, the distance between the ends of the spring was about 0.70 nm and the turn were in the middle between the ends. Therefore, two artificial equilibrium states were possible to create by stretching of the oligo-PF-7 spring, thus forcing the turn to form staking pair either with the left end or with the right end of the spring. Here, these states are referred to as the left-end and the right-end states, respectively. Atomistic snapshots of these two states are shown in FIG. 4a.

FIG. 4 depicts bistability of the oligo-PF-7 spring. (a) The left-end state and the right-end states of the oligo-PF-7 (yellow spheres show fixed atomic groups at the ends of the spring); (b) State diagram of the oligo-PF-7 states with increasing the end-to-end distance D; (c) Spontaneous vibration of the turn between the ends of the oligo-PF-7 spring at D=1.03 nm (P is the distance between the turn and the left end of the spring); (d) Evolution of the probability distribution density for visiting the left-end and the right-end states at different distances D: almost symmetric distribution is seen at D=1.03 nm.

Then, a set of oligo-PF-7 springs were examined with different distances D between the fixed ends to search for the tensile resulting in bistability of the spring. The diagram of the spring states when the end-to-end distance grows is shown in FIG. 4b. Up to the distance D=1.00 nm, the tensile was weak and the oligo-PF-7 turn fluctuated somewhere around the middle. These weakly stretched states of the oligo-PF-7 spring were the same as to the squeezed states of the oligo-PF-5. The median zero-stress point at the middle between the spring ends was a single attractor for the spring dynamics. However, as soon as the distance D exceeded 1.00 nm, an extra attractive point appeared. If the spring was originally in the left-end state, the right-end states (red points in FIG. 4b) were new attractive points, while the bistability barrier was specified by a repulsive area separating the right-end and the original left-end states. The right-end and left-end states were distant from each other at 0.35 nm, so they were distinguished well. The picture was symmetrically reflected when the spring originally was in the right-end state.

Thus, the distance D=1.00 nm between the ends corresponded to the critical tensile at which the spring states experienced bifurcation. Above the critical tensile, the oligo-PF-7 spring became bistable and was able to vibrate spontaneously between the left-end and the right-end states. Near the critical tensile, the left-end state of the spring was dominate, if the spring originally was in this state. In symmetrical situation, the right-end site was dominate. However, the statistics of visiting the left-end and the right-end states turned out to be very sensitive with respect to the tensile of the spring. This sensitivity may result from the π-π interactions of aromatic groups, which degrade sharply with stretching of a stacking pair. In simulations, the two states of the oligo-PF-7 spring became almost equally visited at the distance D=1.03 nm. The most pronounced spontaneous vibrations were achieved by fine tuning of the end-to-end distance and were observed at D=1.03 nm. The spontaneous vibrations trajectory related to D=1.03 nm is shown in FIG. 4c. The vibrations are almost symmetric, and the mean lifetimes of the left-end and the right-end states are both close to T=6.5 ns. This evidenced that the bistability barrier of the oligo-PF-7 is approximately the same as that of the oligo-PF-5 spring extended via pulling of the spring end.

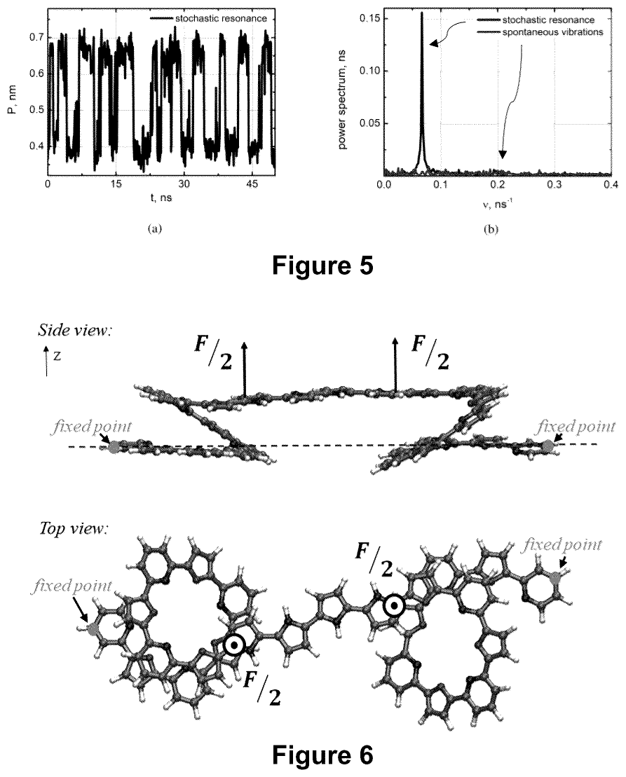

In addition to spontaneous vibrations, the stochastic resonance mode of the oligo-PF-7 spring was examined by applying a weak oscillating force to the turn of spontaneously vibrating spring. The oscillating force was implied by the action of an oscillating electrical field E=E₀ cos(2πvt) on a unit charge preset on the turn, while a compensating charge was put in the simulation box fettled by water molecules. Typical vibrations of the oligo-PF-7 spring in the stochastic resonance mode are shown in FIG. 5a. The power spectrum of the vibrations is shown in FIG. 5b.

FIG. 5. Stochastic resonance of the oligo-PF-7 induced by an oscillating field E=E₀ cos(2π/T): (a) The dynamic trajectory at D=1.03 nm, T=13 ns, and E₀=0.2 Vnm⁻¹; (b) Power spectrum of spontaneous vibrations (red curve) and stochastic resonance (black curve).

The power spectrum unambiguously highlights the stochastic resonance peak. The resonance was obtained with the oscillating field intensity E₀=0.2 Vnm⁻¹ and the frequency

$$v \approx 1 / 2 τ ,$$

where τ was the mean lifetime of the state in the spontaneous vibration mode, i.e. when the period of the oscillating force causing the stochastic resonance was equal to twice the mean lifetime of the state in the spontaneous vibration mode. As in the case of stochastic resonance of the oligo-PF-5 spring, a wide range of amplitudes and frequencies of the oscillating field were scanned to find the maximal response for the stochastic resonance mode. Guided by this scanning, the most representative conditions for the stochastic resonance were chosen, and were provided by the oscillating field with the period close to T=13 ns and the amplitude E₀=0.2 Vnm⁻¹.

### Pyridine-Furan Oligomeric Duffing Oscillator

The oligo-PF-7 spring had fixed ends which played the role of two sites rivaling for the formation of stacking pairs with the spring turn.

Without wishing to be bound by theory, the pendulum-like behavior of the turn in oligo-PF-7 spring may be described by two overlapping stacking potentials associated with the left and right ends of the spring. Thus, a phenomenological potential of the system can be written as:

$$U ( x ) = {U}_{stack} ( x ) + {U}_{stack} ( D - x ) \qquad ( 3 )$$

$${U}_{stack} ( x ) = A [ {( \frac{2 {x}_{min}}{x} )}^{m} - {( \frac{2 {x}_{min}}{x} )}^{n} ] , \qquad ( 4 )$$

Here, m>n>0, xₘᵢₙ is the stacking pair length in the ground-state associated with the minimum of a stacking potential U_{stack}(x), 2xₘᵢₙ is the cutoff radius of the stacking, and D is the distance between the fixed ends of the spring. We can set xₘᵢₙ=0.35 nm. Then, considering the motion of a particle of unit mass in the potential described by equation (3), one can see that if D is close to 2xₘᵢₙ, the overlap of the stacking potentials U_{stack}(x) and U_{stack} (D−x) yields a degenerated minimum right in the middle of the end-to-end distance, so the particle will oscillate around

$${x}_{min} = D / 2.$$

This phenomenological reasoning indicates that bistability should be expected for distances D exceeding the lower limit of D≈2xₘᵢₙ=0.70 nm.

Without wishing to be bound by theory, formal consideration of equation (3) may lead to the conclusion that the potential U(x) is bistable for any D>0.70 nm, so the spontaneous vibrations may be expected, e.g., for D=0.80 nm. If the bistability barrier is approximately equal to k_{B}T or less, then the right-end and the left-end states of the oligo-PF-7 spring may be indistinguishable against the background of fluctuations of dynamic trajectory, and the spontaneous vibrations may not be established. To observe spontaneous vibrations, the bistability barrier should be substantially greater than k_{B}T. Higher bistability barriers appear when the end-to-end distances are sufficiently longer than the lower limit of D=0.70 nm. Indeed, spontaneous vibrations of the oligo-PF-7 spring at distances D ranging from 1.00-1.30 nm, i.e., at the distances about of 3-4 stacking lengths were observed.

On the other hand, if the distance between the ends of the oligo-PF-7 spring is larger than twice the cutoff length of stacking interactions, a wide zone of the zero-stress states may arise in the middle of the end-to-end distance where the turn will predominantly fluctuate. This was exactly what was observed at distances D>1.40 nm.

Thus, to observe the spontaneous vibrations of the turn between the ends, the precise adjustment of the distance between the spring's ends is obligatory, in some embodiments. Such requirement, however, seems natural for short pyridine-furan springs since the π-π interactions are short-ranged, and only one stacking pair is formed with the left or the right end of the oligo-PF-7 spring. Multiple stacking pairs suggest more soft control, so the requirement for the fine-tuning of the end-to-end distance might be weaker.

The next note concerns the stochastic resonance of the oligo-PF-7 spring. If an external oscillating field that drives the spontaneous vibrations of the turn is strong enough, the turn may subsequently move between the ends with the frequency of the oscillating field. Such forced oscillations may have nothing to do with the stochastic resonance, because the stochastic resonance frequency is determined by the lifetimes of the states in the spontaneous vibration mode. Therefore, when dealing with stochastic resonance mode, the limitation on the amplitude of applied oscillating field may also be taken into account. Based on the simulations, E₀=0.3 Vnm⁻¹ was set as the upper limit, below which the stochastic resonance was established.

An additional note concerns the oligo-PF-5 spring. Without wishing to be bound by theory, bistability of PF-springs may be expected since there are competing interactions associated with the stacking and the backbone elasticity. Indeed, if the stacking interaction between the turn and the fixed end of the oligo-PF-5 spring controls the spring elasticity at low tensile and decreases with the stretching, while the elasticity imposed by oligomeric backbone stiffness increases and becomes dominant, a branch of new steady states of the spring can appear and the spring can become bistable. Surprisingly, an oligomeric molecule a few nanometers in size with only one stacking pair realized the appropriately competing interactions. Interestingly, both states of the oligo-PF-5 spring, the squeezed state and the stress-strain state, are shifting with the pulling of the spring, yet the distance between these two states remains approximately the same and equal to 0.3 nm. It is noteworthy that two ground states of pyridine-furan springs, which was specified using quantum calculations corresponding to “good” and “poor” accounting of the π-π interactions, had the same difference of the distances between the adjacent turns.

The region of bistability of the oligo-PF-5 spring was limited by the pulling force equal to approximately F_{dest}=330 pN due to overstretching of the spring. Strong pulling may irreversibly destroy a helix shape of the oligo-PF-5 spring, so the spring irreversibly transits into the overstretched state after some vibrations. The greater the pulling force exceeded the value F_{dest}=330 pN, the faster such transition occurred. Once the spring had reached the overstretched state, it was no longer able return to the squeezed state and the stress-strain state.

An exemplary atomistic representation of a system constructed from two oligo-PF-5 springs rigidly coupled together by an oligomeric bar is shown in FIG. 6. In some embodiments, pyrrole oligomer of length 4 monomeric units (oligo-pyr-4) have rigid coupling of the two PF-spring without significant deformation of the helix geometry of the springs. In some embodiments of a coupled system, the outer diameter of both springs was about 1.4 nm, and the stacking distance between the aromatic rings of a turn of the spring and the fixed end of the spring (FIG. 6, green points) was close to 0.35 nm. In some embodiments, the oligo-pyr-4 bar connecting the springs retained the geometry of the spring.

FIG. 6 depicts two PF oligomeric springs, each with 5 monomeric units, connected with a pyrrole oligomer of length 4 units, in the side and the top views. The bottom end of each PF-spring is fixed by a rigid harmonic force (points). The pulling force is applied to the rigid bar to reach the tensile of the PF-springs related to bistability.

After thermalization of the system of two PF-5 springs coupled by the oligo-pyr-4 bar, two equal pulling forces were applied to the two junction points at which the oligo-pyr-4 bar were connected to the oligo PF-5 springs (see FIG. 6). The pulling forces were directed parallel to the axis of the springs, respectively, they acted orthogonal to the pyrrole bar. Such configuration of the pulling forces allowed to keep the symmetry of the system when stretching the two springs.

After testing the different stretching of two rigidly coupled PF-springs, we found the critical pulling force, at which the system became bistable and vibrate. The total critical force applied to the oligo-pyr-4 bar was about 300 pN, i.e., it was approximately the same as for a single PF-5 spring.

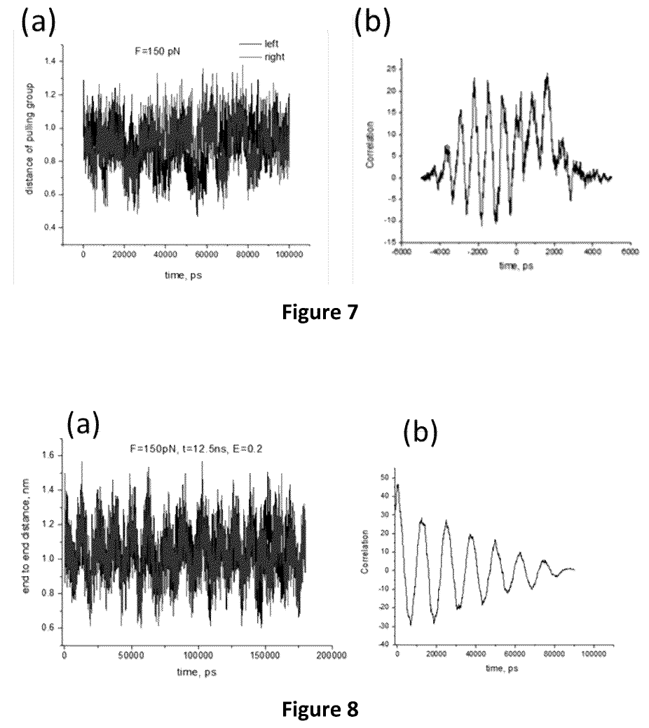

Spontaneous vibrations of the system of two coupled PF-springs are shown in FIG. 7. There are clear vibrations between the two states of the system (FIG. 7a). Surprisingly, the lifetimes of springs in the states are both equal to τ=6.14 ns, i.e., the vibrations of the two PF-springs are symmetric and completely coincide with the vibrations of non-coupled (single) oligo-PF-5 springs. However, unlike the spontaneous vibrations of a single PF-5 spring, which are random and have a wide distribution of frequencies, the vibrations of two coupled PF-springs are visibly synchronized and have a specific oscillating component. The period of this oscillating component corresponds to twice the mean lifetime of the non-coupled PF-5 spring in the states just as the non-coupled spring spontaneously vibrates (FIG. 7b). Thus, the bistability of a system of two rigidly coupled PF-5 springs has intriguing features. On the one hand, the critical force load and the time scales for spontaneous vibrations are very close to those for the non-coupled (single) PF-5 springs. On the other hand, the spontaneous vibrations of two coupled PF-5 springs are partially synchronized, so the system has an oscillating component, the period of which is associated with the average time-characteristics of purely spontaneous vibrations of the oligo-PF-5 springs. The phenomenon of synchronization of spontaneous oscillations of rigidly coupled oligomeric Duffing oscillators could become the basis for the creation of a conceptually new class of nano- and microdevices based on the coordinated behavior of a collective of oligomeric molecular machines.

FIG. 7 depicts spontaneous vibrations of the system of two rigidly coupled PF-springs: (a) Typical vibrations of two coupled PF-springs under the pulling force of 300 pN: rad trajectory for the left spring, and black; (b) cross correlation function for the vibrations of the left and the right springs shows partial synchronization of the spontaneous vibrations of two coupled PF-5 springs.

The stochastic resonance of the system of two coupled PF-5 springs was also examined. To induce the stochastic resonance, an additional oscillating field directed along the pulling forces was applied to the system. The period and amplitude of the oscillating field were the same as in the case of the stochastic resonance of a non-coupled (single) PF-5 springs: the period was T=12.28 ns, and the amplitude was 0.2 V/nm.

The stochastic resonance mode of the system of two rigidly coupled PF-5 springs is shown in FIG. 8. Regular transitions between the two states like the oscillations are clear seen in FIG. 8a. The correlation of oscillations of two rigidly connected PF-springs, shown in FIG. 8b, unambiguously confirms the complete synchronization of the oscillations of the springs. Note, that the total synchronization is achieved even for weak oscillating field driving the stochastic resonance of the system.

FIG. 8 depicts stochastic resonance of two rigidly coupled PF-springs induced by weak oscillating force: (a) Typical vibrations of two coupled PF-springs under the pulling force of 300 pN and the action of weak oscillating force: rad trajectory for the left spring (see FIG. 6), and black trajectory for the right spring; (b) cross correlation function for the vibrations of the left and the right springs shows almost complete synchronization of the vibrations of two rigidly coupled PF-5 springs.

1. A spring-type oligomeric machine comprising:
a conjugated oligomer having a first end and a second end;
wherein the conjugated oligomer has a coiled geometry;
wherein the oligomeric machine exhibits stochastic resonance and/or spontaneous vibrations in a fluid at a first temperature within a critical temperature range, and the oligomeric machine does not exhibit stochastic resonance or spontaneous vibrations in the fluid at a second temperature outside the critical temperature range; and
wherein the oligomeric machine exhibits stochastic resonance and/or spontaneous vibrations in a fluid under at a first force load applied to the oligomeric machine within a critical force range, and the oligomeric machine does not exhibit stochastic resonance or spontaneous vibrations in the fluid at a second force load outside the critical force range.

2. The oligomeric machine according to claim 1, wherein the conjugated oligomer comprises pyridine and/or furan units.

3. The oligomeric machine according to claim 2, wherein the conjugated oligomer comprises 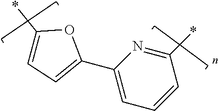
wherein n ranges from 2 to 10.

4. The oligomeric machine according to claim 1, wherein the fluid is an aqueous solution or a gas.

5. The oligomeric machine according to claim 1, wherein the critical temperature range extends from −25° C. to 100° C.

6. The oligomeric machine according to claim 1, wherein the critical force range extends from 10 pN to 1000 pN.

7. The oligomeric machine according to claim 1, wherein the conjugated oligomer has a bandgap and stretching the oligomeric machine increases the bandgap.

8. The oligomeric machine according to claim 1, wherein the conjugated oligomer has a bandgap and stretching the oligomeric machine decreases the bandgap.

9. The oligomeric machine according to claim 1, wherein the conjugated oligomer is piezoelectric and stretching the oligomeric machine results in generation of a voltage associated with the oligomeric machine.

10. The oligomeric machine according to claim 1, wherein the oligomeric machine is configured such that in response to a prescribed amount of energy applied thereto, relative movement occurs between the first end and the second end in a manner causing mechanical action of an associated electric generating element to produce an electrical voltage and/or current.

11. The oligomeric machine according to claim 1, wherein the oligomeric machine further comprises an electric generating element chosen from a piezoelectric element, a nano-particle, a nano-wire, a nano-layer, and a mechanical-electrical transducer; and wherein the oligomeric machine is configured such that in response to a prescribed amount of energy applied thereto, relative movement occurs between the first end and the second end of the conjugated oligomer in a manner causing mechanical action of the electric generating element to produce an electrical voltage and/or current.

12. The oligomeric machine according to claim 1, wherein the oligomeric machine is configured to generate a voltage by performing a mechanical action on a mechanical-electrical transducer comprising at least two capacitor plates.

13. An energy harvesting cell comprising:
a thermal cell,
a mechanical-electrical transducer comprising at least two capacitor plates, and
at least one oligomeric machine according to claim 1;
wherein:
at least one of the capacitor plates is movable, and
the at least one oligomeric machine is thermally coupled to the thermal cell and functionally connected to a mechanical-electrical transducer such that vibrations of the oligomeric machine move a mechanical part of the mechanical-electrical transducer.
